(19) United States
(12) Patent Application Publication
(10) Pub. No.: US 2025/0357259 A1
(43) Pub. Date: Nov. 20, 2025

(54) EMBEDDED COOLING FOR AN INTEGRATED CIRCUIT CONFIGURED WITH A BACKSIDE POWER RAIL

(71) Applicant: NVIDIA CORPORATION, Santa Clara, CA (US)

(72) Inventors: Mahmut Ersin SINANGIL, Los Altos, CA (US); Yujui LIN, Stanford, CA (US); Tahir CADER, Spokane Valley, WA (US); Carl Thomas GRAY, Apex, NC (US); John Michael WILSON, Wake Forest, NC (US)

(21) Appl. No.: 18/667,255

(22) Filed: May 17, 2024

(51) Int. Cl. H01L 23/42; H01L 23/528; H05K 1/02

(52) U.S. Cl. CPC H01L 23/42; H05K 1/0272; H01L 23/5286; H05K 2201/064

(57) ABSTRACT

According to various embodiments, a packaged integrated circuit device includes: a first semiconductor substrate and a second semiconductor substrate. The first semiconductor substrate includes: an integrated circuit, a region of signal layers residing on a first side of the first semiconductor substrate, and a region of power delivery layers residing on a second side of the first semiconductor substrate. The second semiconductor substrate is coupled to the region of signal layers, wherein a first side of the second semiconductor substrate is coupled to the region of signal layers, and a second side of the second semiconductor substrate includes a plurality of fluidic channels.

### BACKGROUND

### Field of the Various Embodiments

The various embodiments relate generally to computer architecture and electronics and, more specifically, to embedded cooling for an integrated circuit configured with a backside power rail.

### Description of the Related Art

The backside power rail (BPR) is an integrated circuit (IC) architecture that can increase the density of transistors in an IC and decrease the voltage drop (also referred to as “IR drop”) within an IC. In conventional ICs, transistors are formed on one surface of a semiconductor substrate, and multiple layers of signal connections and power connections are then formed on top of the transistors. By contrast, in the BPR architecture, the transistors and signal connection layers of an IC are formed on one surface of the semiconductor substrate while the power connection layers are formed on the opposite surface of the semiconductor substrate. This optimized circuit routing enables closer spacing of the IC transistors, and can significantly reduce voltage drop within the IC.

One drawback of the BPR architecture is that the architectural layout makes removing heat from an IC more difficult, more so as the power density (and, therefore, heat generation) of the more densely packed transistors of a BPR IC increases. In particular, in the BPR architecture, the transistor layer of a BPR IC is separated from a heat sink or other thermal solution by the signal connection layers rather than by the semiconductor substrate. The signal connection layers are primarily composed of dielectric materials that have lower thermal conductivity than semiconductor materials such as silicon (Si). As a result, in the BPR architecture, there is more thermal resistance between the heat-generating transistors and the thermal solution than in a conventional IC architecture. Consequently, conventional approaches for heat removal, such as the attachment of a vapor chamber, a cold plate, or a fan-cooled heat-sink, oftentimes cannot dissipate heat sufficiently to enable the ICs in a BPR architecture to operate at target levels.

As the foregoing illustrates, what is needed in the art are more effective techniques for cooling integrated circuits in BPR architectures.

### SUMMARY

According to various embodiments, a packaged integrated circuit device includes: a first semiconductor substrate and a second semiconductor substrate. The first semiconductor substrate includes: an integrated circuit, a region of signal layers residing on a first side of the first semiconductor substrate, and a region of power delivery layers residing on a second side of the first semiconductor substrate. The second semiconductor substrate is coupled to the region of signal layers, wherein a first side of the second semiconductor substrate is coupled to the region of signal layers, and a second side of the second semiconductor substrate includes a plurality of fluidic channels.

At least one technical advantage of the disclosed design relative to the prior art is that the disclosed design enables more heat to be removed from the integrated circuits in a backside power rail architecture relative to what can be achieved in conventional integrated circuit designs. Another technical advantage of the disclosed design is that manufacturing the backside power rail integrated circuit is facilitated by the enhanced structural support provided by the additional substrate that is included in the design to incorporate the various fluidic channels. These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a conceptual illustration of a computer system configured to implement one or more aspects of the various embodiments.

FIG. 2 is a conceptual plan view of a packaged integrated circuit (IC) device mounted on a printed circuit board, according to various embodiments.

FIG. 3 is a conceptual cross-sectional view of the IC of FIG. 2, according to various embodiments.

FIG. 4 is a conceptual cross-sectional view of a transistor region of the IC of FIG. 2, according to various embodiments.

FIG. 5 is a conceptual plan view of a packaged IC device during operation, according to various embodiments.

FIG. 6 is a conceptual plan view of a packaged IC device that includes a heat-spreader layer, according to various embodiments.

FIG. 7 is a conceptual cross-sectional view of IC of FIG. 2, according to various other embodiments.

For clarity, identical reference numbers have been used, where applicable, to designate identical elements that are common between figures. It is contemplated that features of one embodiment may be incorporated in other embodiments without further recitation.

### DETAILED DESCRIPTION

In the following description, numerous specific details are set forth to provide a more thorough understanding of the various embodiments. However, it will be apparent to one of skilled in the art that the inventive concepts may be practiced without one or more of these specific details.

### System Overview

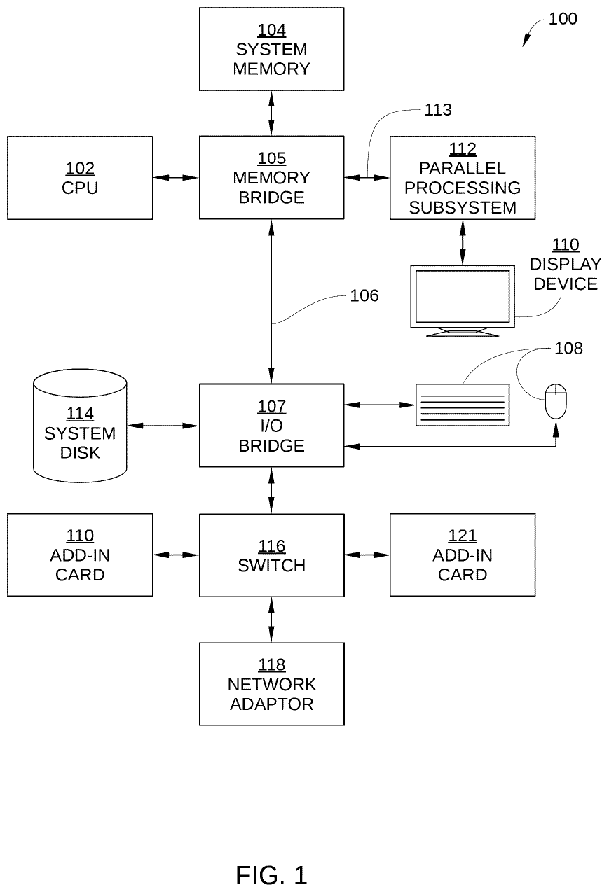

FIG. 1 is a conceptual illustration of a computer system 100 configured to implement one or more aspects of the various embodiments. As shown, system 100 includes a central processing unit (CPU) 102 and a system memory 104 communicating via a bus path that may include a memory bridge 105. CPU 102 includes one or more processing cores, and, in operation, CPU 102 is the master processor of system 100, controlling and coordinating operations of other system components. System memory 104 stores software applications and data for use by CPU 102. CPU 102 runs software applications and optionally an operating system. Memory bridge 105, which may be, e.g., a Northbridge chip, is connected via a bus or other communication path (e.g., a HyperTransport link) to an I/O (input/output) bridge 107. I/O bridge 107, which may be, e.g., a Southbridge chip, receives user input from one or more user input devices 108 (e.g., keyboard, mouse, joystick, digitizer tablets, touch pads, touch screens, still or video cameras, motion sensors, and/or microphones) and forwards the input to CPU 102 via memory bridge 105.

A display processor 112 is coupled to memory bridge 105 via a bus or other communication path (e.g., a PCI Express, Accelerated Graphics Port, or HyperTransport link); in one embodiment display processor 112 is a graphics subsystem that includes at least one graphics processing unit (GPU) and graphics memory. Graphics memory includes a display memory (e.g., a frame buffer) used for storing pixel data for each pixel of an output image. Graphics memory can be integrated in the same device as the GPU, connected as a separate device with the GPU, and/or implemented within system memory 104.

Display processor 112 periodically delivers pixels to a display device 110 (e.g., a screen or conventional CRT, plasma, OLED, SED or LCD based monitor or television). Additionally, display processor 112 may output pixels to film recorders adapted to reproduce computer generated images on photographic film. Display processor 112 can provide display device 110 with an analog or digital signal. In various embodiments, a graphical user interface is displayed to one or more users via display device 110, and the one or more users can input data into and receive visual output from the graphical user interface.

A system disk 114 is also connected to I/O bridge 107 and may be configured to store content and applications and data for use by CPU 102 and display processor 112. System disk 114 provides non-volatile storage for applications and data and may include fixed or removable hard disk drives, flash memory devices, and CD-ROM, DVD-ROM, Blu-ray, HD-DVD, or other magnetic, optical, or solid state storage devices.

A switch 116 provides connections between I/O bridge 107 and other components such as a network adapter 118 and various add-in cards 120 and 121. Network adapter 118 allows system 100 to communicate with other systems via an electronic communications network, and may include wired or wireless communication over local area networks and wide area networks such as the Internet.

Other components (not shown), including USB or other port connections, film recording devices, and the like, may also be connected to I/O bridge 107. For example, an audio processor may be used to generate analog or digital audio output from instructions and/or data provided by CPU 102, system memory 104, or system disk 114. Communication paths interconnecting the various components in FIG. 1 may be implemented using any suitable protocols, such as PCI (Peripheral Component Interconnect), PCI Express (PCI-E), AGP (Accelerated Graphics Port), HyperTransport, or any other bus or point-to-point communication protocol(s), and connections between different devices may use different protocols, as is known in the art.

In one embodiment, display processor 112 is configured as a processing subsystem that incorporates circuitry optimized for graphics and video processing, including, for example, video output circuitry, and constitutes a graphics processing unit (GPU). In another embodiment, display processor 112 is configured as a processing subsystem that incorporates circuitry optimized for general purpose processing. In yet another embodiment, display processor 112 may be integrated with one or more other system elements, such as the memory bridge 105, CPU 102, and I/O bridge 107 to form a system on chip (SoC). In still further embodiments, display processor 112 is omitted and software executed by CPU 102 performs the functions of display processor 112.

Pixel data can be provided to display processor 112 directly from CPU 102. In some embodiments, instructions and/or data representing a scene are provided to a render farm or a set of server computers, each similar to system 100, via network adapter 118 or system disk 114. The render farm generates one or more rendered images of the scene using the provided instructions and/or data. These rendered images may be stored on computer-readable media in a digital format and optionally returned to system 100 for display. Similarly, stereo image pairs processed by display processor 112 may be output to other systems for display, stored in system disk 114, or stored on computer-readable media in a digital format.

Alternatively, CPU 102 provides display processor 112 with data and/or instructions defining the desired output images, from which display processor 112 generates the pixel data of one or more output images, including characterizing and/or adjusting the offset between stereo image pairs. The data and/or instructions defining the desired output images can be stored in system memory 104 or graphics memory within display processor 112. In an embodiment, display processor 112 includes 3D rendering capabilities for generating pixel data for output images from instructions and data defining the geometry, lighting shading, texturing, motion, and/or camera parameters for a scene. Display processor 112 can further include one or more programmable execution units capable of executing shader programs, tone mapping programs, and the like.

Further, in other embodiments, CPU 102 or display processor 112 may be replaced with or supplemented by any technically feasible form of processing device configured to process data and execute program code. Such a processing device could be, for example, a central processing unit (CPU), a graphics processing unit (GPU), an application-specific integrated circuit (ASIC), a field-programmable gate array (FPGA), and so forth. In various embodiments any of the operations and/or functions described herein can be performed by CPU 102, display processor 112, or one or more other processing devices or any combination of these different processors. In other contemplated embodiments, system 100 may or may not include other elements shown in FIG. 1.

CPU 102, render farm, and/or display processor 112 can employ any surface or volume rendering technique known in the art to create one or more rendered images from the provided data and instructions, including rasterization, scanline rendering REYES or micropolygon rendering, ray casting, ray tracing, image-based rendering techniques, and/or combinations of these and any other rendering or image processing techniques known in the art.

It will be appreciated that the system shown herein is illustrative and that variations and modifications are possible. The connection topology, including the number and arrangement of bridges, may be modified as desired. For instance, in some embodiments, system memory 104 is connected to CPU 102 directly rather than through a bridge, and other devices communicate with system memory 104 via memory bridge 105 and CPU 102. In other alternative topologies display processor 112 is connected to I/O bridge 107 or directly to CPU 102, rather than to memory bridge 105. In still other embodiments, I/O bridge 107 and memory bridge 105 might be integrated into a single chip. The particular components shown herein are optional; for instance, any number of add-in cards or peripheral devices might be supported. In some embodiments, switch 116 is eliminated, and network adapter 118 and add-in cards 120, 121 connect directly to I/O bridge 107.

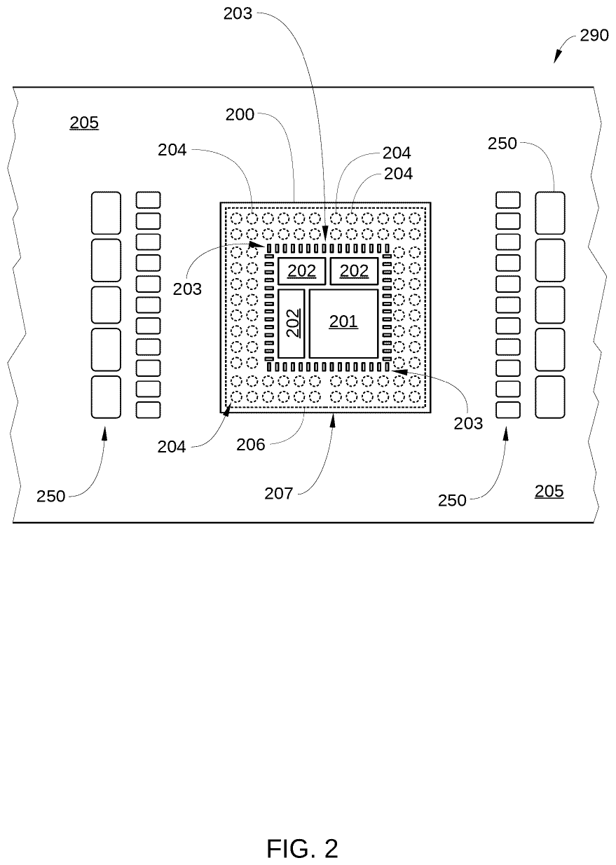

FIG. 2 is a conceptual plan view of a packaged integrated circuit (IC) device 200 mounted on a printed circuit board (PCB) 205, according to various embodiments. When mounted on PCB 205 as shown, packaged IC device 200 operates as a card-based processing subsystem 290, such as a graphics card, a network interface card, and/or the like. As such, packaged IC device 200 can be implemented as parallel processing subsystem 112, and/or as add-in cards 120, 121 in FIG. 1. Alternatively, when not mounted on PCB 205, packaged IC device 200 can be implemented as a packaged processing device, such as a microprocessor or system-on-chip (SoC). In such embodiments, packaged IC device 200 can be implemented as CPU 102 and/or parallel processing subsystem 112 in FIG. 1.

In practice, a thermal solution is typically mounted on or coupled to a top surface of the packaged IC device 200, such as a vapor chamber, a liquid-cooled cold plate, a fan-cooled heat sink, and/or the like. For clarity, in the embodiment illustrated in FIG. 2, packaged IC device 200 is shown without a heat sink or other thermal solution mounted thereon.

Packaged IC device 200 is a packaged electronic device (such as an IC package) that includes an IC 201 (such as a CPU, GPU, or other processor). IC 201 is mounted on a packaging substrate 206 (dashed lines) and/or an interposer substrate (not shown), and is disposed within a sealed IC package 207. In the embodiment illustrated in FIG. 2, packaged IC device 200 further includes one or more high-bandwidth memories 202 that are also mounted on packaging substrate 206 and/or the interposer substrate and are disposed within IC package 207. IC 201 is communicatively coupled to PCB 205 via a plurality of electrical connections 204, such as solder balls, solder bumps, and/or microbumps. In some embodiments, packaged IC device 200 further includes other electronic components 203 disposed within IC package 207 and mounted on substrate 206 and/or the interposer substrate, such as capacitors. In some embodiments, other electronic components 250 are also mounted on PCB 205, such as memory devices and/or power devices associated with packaged IC device 200.

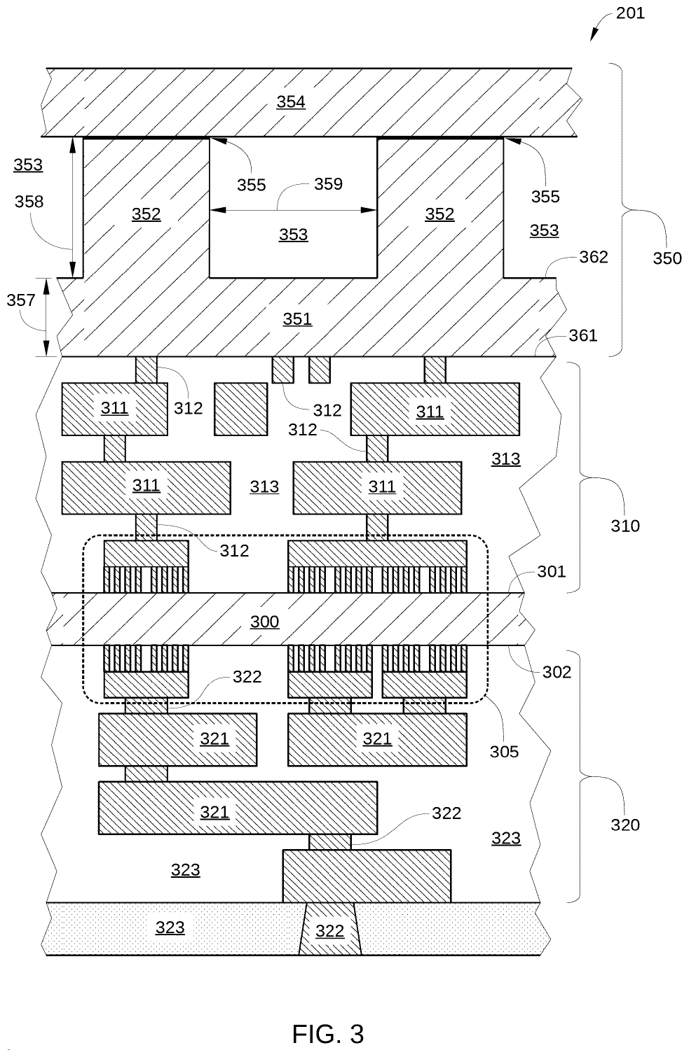

According to various embodiments, IC 201 is configured with a backside power rail (BPR) architecture. In such embodiments, the transistors and signal connection layers of IC 201 are formed on one surface of the semiconductor substrate of IC 201 while the power connection layers are formed on the opposite surface of the semiconductor substrate. In operation, IC 201 may be limited in performance based on operating temperature. According to various embodiments, IC 201 is further configured with an embedded cooling structure that greatly increases heat dissipation from IC 201 compared to conventional thermal solutions. As a result, the performance of IC 201 is enhanced by the inclusion of the embedded cooling structure. One embodiment of IC 201 and the embedded cooling structure is described below in conjunction with FIG. 3.

Embedded Cooling with Backside Power Rail Architectures

FIG. 3 is a conceptual cross-sectional view of IC 201, according to various embodiments. As shown, IC 201 includes a first semiconductor substrate 300 with transistors (not shown) and a region of signal layers 310 formed on a first side 301 and a region of power delivery layers 320 formed on a second side 302. First semiconductor substrate 300 can be any substrate suitable for use in an integrated circuit, such as a portion of a wafer or other substrate that includes silicon (Si), gallium arsenide (GaAs), indium phosphide (InP), and the like.

Region of signal layers 310 provides signal connections between the transistors and other devices formed on first semiconductor substrate 300 and/or electrical connections 204 of packaged ID device 200 (shown in FIG. 2). In the embodiment illustrated in FIG. 3, region of signal layers 310 includes multiple layers of electrically conductive interconnects 311 and associated inter-layer vias 312, disposed within various layers of dielectric material 313.

Region of power delivery layers 320 provides power connections to the transistors and other devices formed on first semiconductor substrate 300 and between the transistors and other devices and electrical connections 204 of packaged ID device 200. In the embodiment illustrated in FIG. 3, region of power delivery layers 320 includes multiple layers of electrically conductive interconnects 321 and associated inter-layer vias 322, disposed within various layers of dielectric material 323. Region of power delivery layers 320 forms a backside power distribution network that is on an opposite side of first semiconductor substrate 300 from region of signal layers 310. Thus, IC 201 has a BPR architecture. As such, IC 201 can have higher transistor density than conventional ICs, and therefore may be subject to higher power density and concomitant heat generation. According to various embodiments, improved cooling is provided to IC 201 by an embedded cooling structure 350 included in or coupled to IC 201.

Embedded cooling structure 350 provides enhanced cooling of IC 201 relative to conventional thermal solutions, which are generally coupled to a surface of IC 201 or of the IC package that includes IC 201. In the embodiment illustrated in FIG. 3, embedded cooling structure 350 includes a second semiconductor substrate 351 that has a plurality of fluidic channels 353 formed thereon. As shown, second semiconductor substrate 351 is coupled to region of signal layers 310 on a first side 361 of second semiconductor substrate 351, and has the plurality of fluidic channels 353 formed on a second side 362 of second semiconductor substrate 351. Embedded cooling structure 350 further includes a lid structure 354 that encloses the plurality of fluidic channels 353. Thus, fluidic channels 353 are sealed and can be employed as conduits for a cooling fluid, such as water, alcohol, a water-alcohol mixture, and/or the like.

In some embodiments, a microelectromechanical systems (MEMS) process is employed to form fluidic channels 353 on second side 362 of second semiconductor substrate 351. In some embodiments, one or more MEMS etching processes are employed to form fluidic channels 353. Alternatively or additionally, in some embodiments, one or more MEMS deposition processes are employed to form fluidic channels 353. In such embodiments, fluidic channels 353 can be formed via an array of projections 352 deposited on second side 362 of second semiconductor substrate 351. After formation of fluidic channels 353, lid structure 354 is bonded onto second semiconductor substrate 351 to enclose fluidic channels 353. Fluidic channels 353 can be formed with any suitable cross section for a targeted flow rate of the cooling fluid. For example, in some embodiments, fluidic channels 353 can be microfluidic channels having a depth 358 on the order of about 50-500 microns and a width on the order of about 50-200 microns.

Because second semiconductor substrate 351 is a separate substrate from first semiconductor substrate 300, there are no transistors or other devices formed on second semiconductor substrate 351. Thus, fluidic channels 353 can be formed on second semiconductor substrate 351 using fabrication processes that are generally not compatible with first semiconductor substrate 300. For example, MEMS processes are generally incompatible with the complementary metal-oxide semiconductor (CMOS) process employed to generate the transistors and other devices of IC 201. Therefore, fluidic channels 353 can be formed on second semiconductor substrate 351 using MEMS processes, while the transistors of IC 201 and the transistors and other devices of IC 201 can be formed on first semiconductor substrate 300 using CMOS processes.

In some embodiments, second semiconductor substrate 351 can be employed as a carrier wafer for facilitating the formation of region of power delivery layers 320 on second side 302. In such embodiments, after fluidic channels 353 are formed on second semiconductor substrate 351 and region of signal layers 310 is formed on first semiconductor substrate 300, second semiconductor substrate 351 can be bonded to first semiconductor substrate 300. Due to the structural support of second semiconductor substrate 351, first semiconductor substrate 300 can then be thinned and region of power delivery layers 320 can be formed thereon with lower risk of being damaged.

It is noted that the cooling fluid flowing through fluidic channels 353 is separated from the heat-generating transistors of IC 201 by region of signal layers 310 and a thickness 357 of second semiconductor substrate 351. Because second semiconductor substrate 351 includes no transistors or other devices, second semiconductor substrate 351 can undergo an aggressive thinning process without endangering the integrity or the functionality of IC 201. Thus, in some embodiments, thickness 357 of second semiconductor substrate 351 can be reduced to a few hundred microns (e.g., 300-500). As a result, the thermal resistance between the heat-generating regions of IC 201 (e.g., the transistors on first side 301 of semiconductor substrate 300) and the cooling fluid in fluidic channels 353 is low. Specifically, heat generated by transistors on first side 301 is separated from fluidic channels by region of signal layers 310 and thickness 357 of second semiconductor substrate 351. By contrast, cooling fluid in a conventional thermal solution is separated from the heat-generating regions of an IC by one or more additional structures that add significant heat resistance, such as a package lid, one or more layers of thermal interface material, and the wall of the thermal solution that contains the cooling fluid. Each of these structures can be several hundred microns or more in thickness, resulting in significant thermal resistance.

In some embodiments, lid structure 354 includes a semiconductor material that is similar to second semiconductor substrate 351. In such embodiments, lid structure 354 can be bonded or otherwise coupled to second semiconductor substrate 351 using one or more semiconductor bonding techniques known in the art, including: adhesive bonding, anodic bonding, eutectic bonding, fusion bonding, glass frit bonding, metal diffusion bonding, solid-liquid inter-diffusion (SLOD), and/or the like. Alternatively, in some embodiments, lid structure 354 includes a material that has a coefficient of thermal expansion that does not match a coefficient of thermal expansion of a material included in second semiconductor substrate 351. For example, in some embodiments, when the material of lid structure 354 has a first coefficient of thermal expansion that differs by about 10% or more than a second coefficient of thermal expansion of a material included in second semiconductor substrate 351, the first coefficient of thermal expansion does not match the second coefficient of thermal expansion. In such embodiments, lid structure 354 can be bonded or otherwise coupled to second semiconductor substrate 351 using an elastic material 355, such as an epoxy, an adhesive, and/or an elastomeric gasket.

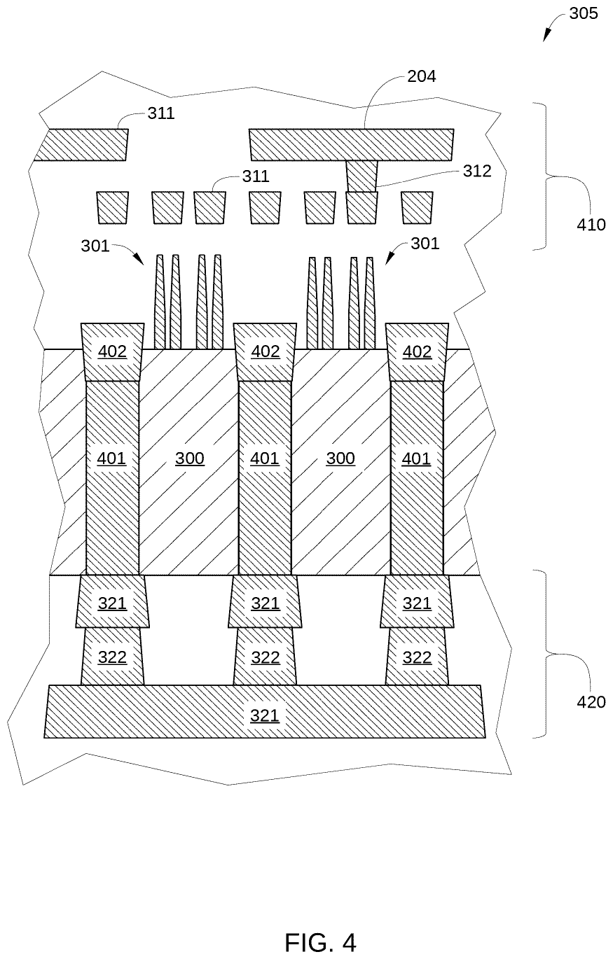

As shown, IC 201 includes a transistor region 305 proximate first semiconductor substrate 300. Transistor region 305 is described in greater detail below in conjunction with FIG. 4.

FIG. 4 is a conceptual cross-sectional view of transistor region 305 of IC 201, according to various embodiments. As shown, transistor region 305 includes first semiconductor substrate 300, transistors 301, a portion 410 of region of signal layers 310, and a portion 420 of region of power delivery layers 320. Transistors 301 can be fin field-emission transistors (fin-FETs) as shown, or any other technically feasible transistors, diodes, or other devices. Portion 410 includes various electrically conductive interconnects 311 and associated inter-layer vias 312 within region of signal layers 310 and portion 420 includes various electrically conductive interconnects 321 and associated inter-layer vias 322 of a backside power distribution network. Transistor region 305 further includes through-silicon vias 401 and buried power rails 402 that route power from the backside power distribution network through first semiconductor substrate 300 to transistors 301 and other devices formed on first semiconductor substrate 300.

Embedded Cooling with Heat Conduction Structures

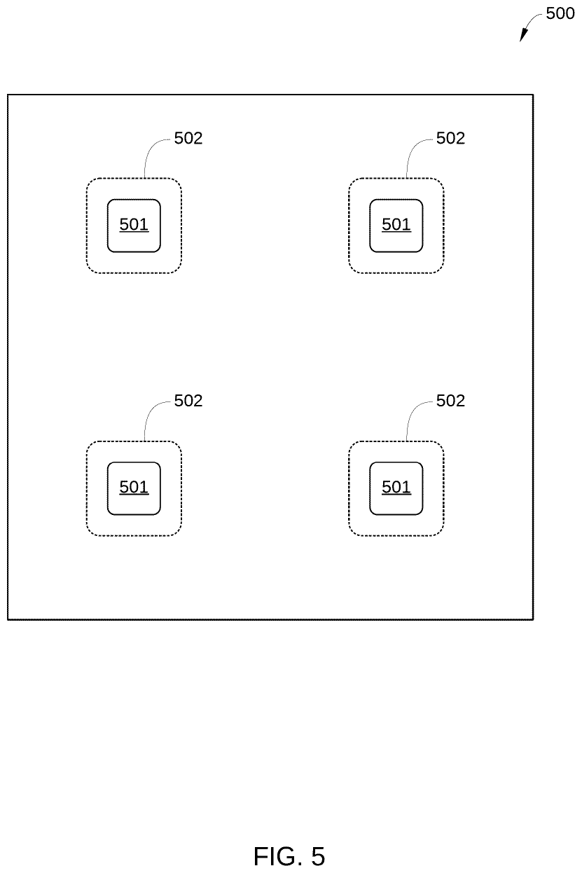

In some embodiments, a packaged IC device includes one or more heat conduction structures to further enhance heat dissipation during operation. Such heat conduction structures can ameliorate or reduce higher temperature regions within a packaged IC device by facilitating the conduction of heat away from such regions to other areas of the packaged IC device and/or toward an embedded cooling structure similar to that described above in conjunction with FIG. 3. For example, in many instances, temperature distribution within a packaged IC device during operation can be very uneven, with hot spots developing around portions of the packaged IC device that generate the most heat. One such instance is described below in conjunction with FIG. 5.

FIG. 5 is a conceptual plan view of a packaged IC device 500 during operation, according to various embodiments. In some embodiments, packaged IC device 500 can be consistent with packaged IC device 200 of FIG. 2. As shown, packaged IC device 500 includes four processing cores 501 that generate the majority of heat during operation of packaged IC device 500. Therefore, even though packaged IC device 500 includes an embedded cooling structure with fluidic channels, hot spots 502 may develop due to the localized heat generation associated with processing cores 501. As a result, due to the over-heating of hot spots 502, throttling of the performance of processing cores 501 may be required, even while other regions of packaged IC device 500 operate under an operational temperature threshold.

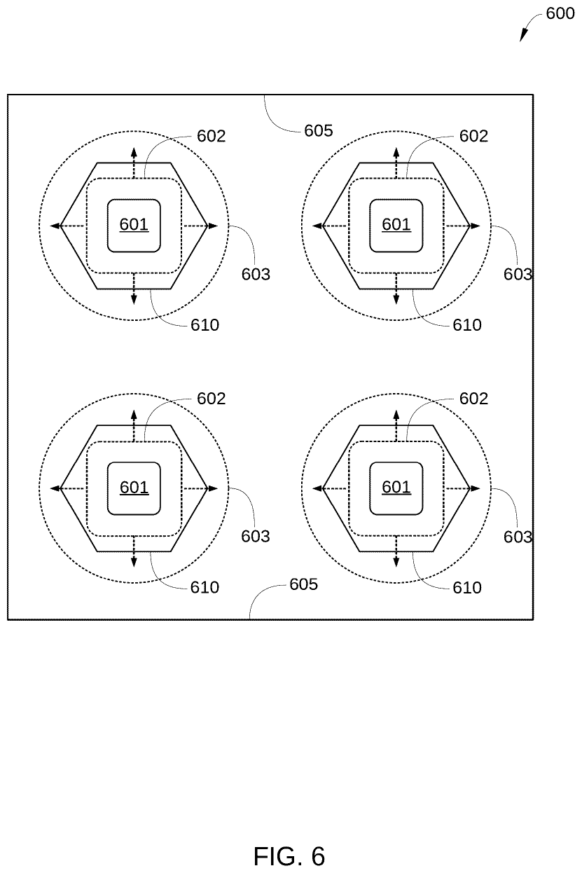

In some embodiments, to facilitate heat dissipation from hot spots 502, one or more heat conduction structures are included in packaged IC device 500. One such embodiment is described below in conjunction with FIG. 6.

FIG. 6 is a conceptual plan view of a packaged IC device 600 that includes a heat-spreader layer, according to various embodiments. In some embodiments, packaged IC device 600 can be consistent with packaged IC device 200 of FIG. 2, with the addition of one or more heat-spreader layers 610. In the embodiment illustrated in FIG. 6, each heat-spreader layer 610 is disposed proximate a respective hot spot 602 that is caused by a processing core 601. As a result, thermal energy concentrated in hot spots 602 is conducted away from processing cores 601 to a larger region 603. Alternatively, in some embodiments, packaged IC device 600 includes a single heat-spreader layer 610 that is disposed proximate most or all of processing cores 601. In yet other embodiments, packaged IC device 600 includes any other technically feasible configuration of heat-spreader layer, such as one or more heat-spreader layers that extend to one or more edges 605 of packaged IC device 600 and/or extend into or are disposed in multiple layers of packaged IC device 600.

In the embodiment illustrated in FIG. 6, heat-spreader layers 610 are depicted as hexagonal regions. In other embodiments, heat-spreader layers 610 can have any technically feasible shape (e.g., circular, rectangular, and the like) or technically feasible thickness.

Heat-spreader layer 610 can include any technically feasible heat-conducting material suitable for use on or within packaged IC device 600. Examples of heat-conducting materials included in heat-spreader layer 610 includes one or more of chemical-vapor deposition diamond, silver (Ag), copper (Cu), gold (Au), aluminum nitride (AlN), silicon carbide (SiC), aluminum (Al), tungsten (W), graphite, and/or the lie. In some embodiments, heat spreader layer 610 is limited to being an electrically insulative material, to prevent interfering with operation of packaged IC device 600. Additionally or alternatively, in some embodiments, the locations in which heat spreader layer 610 is formed on or within packaged IC device 600 are selected to prevent electrical shorting and/or unwanted electrical interactions (such as induction).

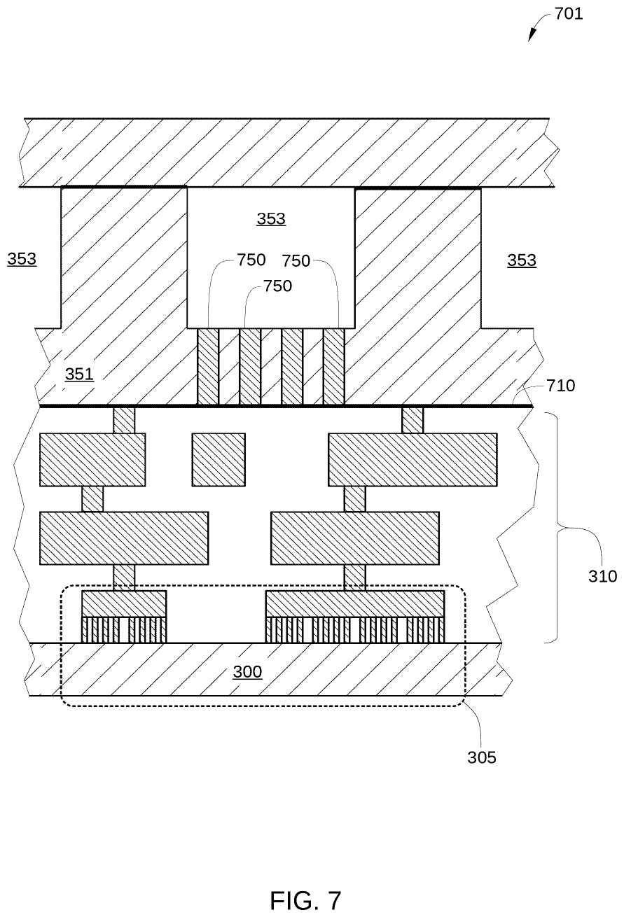

In some embodiments, a packaged IC device includes one or more heat-spreader layers and/or one or more heat-transfer vias to facilitate heat dissipation away from hot spots within the packaged IC device and toward fluidic channels included in the packaged IC device. One such embodiment is described below in conjunction with FIG. 7.

FIG. 7 is a conceptual cross-sectional view of an IC 701, according to various embodiments. IC 701 is included in a packaged IC device similar to packaged IC device 200 of FIG. 2. IC 701 is similar to IC 201 in FIGS. 2 and 3, with the addition of a heat-spreader layer 710 and/or one or more heat-transfer vias 750. In the embodiment illustrated in FIG. 7, heat-spread layer 710 is formed, deposited, or otherwise disposed at an interface between region of signal layers 310 and second semiconductor substrate 351. In other embodiments, heat-spreader layer 710 may be formed, deposited, or otherwise disposed at one or more other locations within IC 701.

In the embodiment illustrated in FIG. 7, heat-transfer vias 750 are formed in second semiconductor substrate 351 and are positioned to facilitate heat transfer from transistor region 305 and region of signal layers 310 to the cooling fluid within fluidic channels 353. Consequently, in FIG. 7, heat-transfer vias 750 are formed between fluidic channels 353 and region of signal layers 310 and are completely or partially filled with a material having a relatively high thermal conductivity. Examples of such a material include copper, silver, aluminum, CVD diamond, and/or the like. As a result, heat transfer through second semiconductor substrate 351 is greatly facilitated. For example, the thermal conductivity of silicon is approximately 140 W/mK, whereas the thermal conductivity of copper is approximately 400 W/mK. Thus, copper-filled heat-transfer vias 750 can greatly increase heat transfer from region of signal layers 310 to the cooling fluid in fluidic channels 353. In some embodiments, one or more heat-transfer vias 750 are positioned in second semiconductor substrate 351 to correspond to an area of high heat output of IC 701, such as a hot spot 502 in FIG. 5.

In sum, the various embodiments shown and provided herein set forth techniques for cooling a packaged IC device that is configured according to a BPR architecture. In the embodiments, the packaged IC device includes an embedded cooling structure formed in an additional semiconductor substrate that is bonded to the semiconductor substrate that includes transistors and other devices. In some embodiments, one or more heat-spreader layers are also included in the packaged IC device.

At least one technical advantage of the disclosed design relative to the prior art is that the disclosed design enables more heat to be removed from the integrated circuits in a backside power rail architecture relative to what can be achieved in conventional integrated circuit designs. Another technical advantage of the disclosed design is that manufacturing the backside power rail integrated circuit is facilitated by the enhanced structural support provided by the additional substrate that is included in the design to incorporate the various fluidic channels. These technical advantages provide one or more technological advancements over prior art approaches.
1. In some embodiment, a packaged integrated circuit device includes: a first semiconductor substrate that includes: an integrated circuit, a region of signal layers residing on a first side of the first semiconductor substrate, and a region of power delivery layers residing on a second side of the first semiconductor substrate; and a second semiconductor substrate coupled to the region of signal layers, wherein a first side of the second semiconductor substrate is coupled to the region of signal layers, and a second side of the second semiconductor substrate includes a plurality of fluidic channels.
2. The packaged integrated circuit device of clause 1, further comprising a lid structure that is coupled to the second side of the second semiconductor substrate and encloses the plurality of fluidic channels.
3. The packaged integrated circuit device of clauses 1 or 2, wherein the lid structure comprises a material having a first coefficient of thermal expansion that matches a second coefficient of thermal expansion of a material included in the second semiconductor substrate.
4. The packaged integrated circuit device of any of clauses 1-3, wherein the lid structure comprises a material having a first coefficient of thermal expansion that does not match a second coefficient of thermal expansion of a material included in the second semiconductor substrate, and the lid structure is coupled to the second side of the second semiconductor substrate via an elastic material.
5. The packaged integrated circuit device of any of clauses 1-4, wherein the region of power delivery layers includes a plurality of power rails for distributing power to the integrated circuit.
6. The packaged integrated circuit device of any of clauses 1-5, wherein each power rail in the plurality of power rails is electrically coupled to a through-silicon via included in the first semiconductor substrate.
7. The packaged integrated circuit device of any of clauses 1-6, wherein the first semiconductor substrate includes a plurality of through-silicon vias that are electrically coupled to the region of power delivery layers.
8. The packaged integrated circuit device of any of clauses 1-7, further comprising a heat-spreader layer disposed on the first side of the second semiconductor substrate.
9. The packaged integrated circuit device of any of clauses 1-8, wherein the heat-spreader layer comprises chemical-vapor deposition diamond, silver (Ag), copper (Cu), gold (Au), aluminum nitride (AlN), silicon carbide (SiC), aluminum (Al), tungsten (W), or graphite.
10. The packaged integrated circuit device of any of clauses 1-9, wherein the heat-spreader layer is disposed proximate to a processing core of the integrated circuit.
11. The packaged integrated circuit device of any of clauses 1-10, wherein the heat-spreader layer contacts one or more heat-transfer vias included in the second semiconductor substrate.
12. The packaged integrated circuit device of any of clauses 1-11, wherein the second semiconductor substrate includes one or more heat-transfer vias.
13. The packaged integrated circuit device of any of clauses 1-12, wherein the one or more heat-transfer vias are disposed proximate to a processing core of the integrated circuit.
14. The packaged integrated circuit device of any of clauses 1-13, wherein the fluidic channels comprise an array of projections that reside on the second side of the second semiconductor substrate.
15. In some embodiments, a card-based processing subsystem includes: a printed circuit board; and a packaged integrated circuit device that is mounted on the printed circuit board and comprises: a first semiconductor substrate that includes: an integrated circuit, a region of signal layers residing on a first side of the first semiconductor substrate, and a region of power delivery layers residing on a second side of the first semiconductor substrate; and a second semiconductor substrate coupled to the region of signal layers, wherein a first side of the second semiconductor substrate is coupled to the region of signal layers, and a second side of the second semiconductor substrate includes a plurality of fluidic channels.
16. The card-based processing subsystem of clause 15, further comprising a lid structure that is coupled to the second side of the second semiconductor substrate and encloses the plurality of fluidic channels.
17. The card-based processing subsystem of clauses 15 or 16, wherein the region of power delivery layers includes a plurality of power rails for distributing power to the integrated circuit.
18. The card-based processing subsystem of any of clauses 15-17, wherein each power rail in the plurality of power rails is electrically coupled to a through-silicon via included in the first semiconductor substrate.
19. The card-based processing subsystem of any of clauses 15-18, wherein the first semiconductor substrate includes a plurality of through-silicon vias that are electrically coupled to the region of power delivery layers.
20. The card-based processing subsystem of any of clauses 15-19, further comprising a heat-spreader layer disposed on the first side of the second semiconductor substrate.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

While the preceding is directed to embodiments of the present disclosure, other and further embodiments of the disclosure may be devised without departing from the basic scope thereof, and the scope thereof is determined by the claims that follow.

What is claimed is:

1. A packaged integrated circuit device, comprising:
a first semiconductor substrate that includes:
an integrated circuit,
a region of signal layers residing on a first side of the first semiconductor substrate, and
a region of power delivery layers residing on a second side of the first semiconductor substrate; and
a second semiconductor substrate coupled to the region of signal layers, wherein a first side of the second semiconductor substrate is coupled to the region of signal layers, and a second side of the second semiconductor substrate includes a plurality of fluidic channels.

2. The packaged integrated circuit device of claim 1, further comprising a lid structure that is coupled to the second side of the second semiconductor substrate and encloses the plurality of fluidic channels.

3. The packaged integrated circuit device of claim 2, wherein the lid structure comprises a material having a first coefficient of thermal expansion that matches a second coefficient of thermal expansion of a material included in the second semiconductor substrate.

4. The packaged integrated circuit device of claim 2, wherein the lid structure comprises a material having a first coefficient of thermal expansion that does not match a second coefficient of thermal expansion of a material included in the second semiconductor substrate, and the lid structure is coupled to the second side of the second semiconductor substrate via an elastic material.

5. The packaged integrated circuit device of claim 1, wherein the region of power delivery layers includes a plurality of power rails for distributing power to the integrated circuit.

6. The packaged integrated circuit device of claim 5, wherein each power rail in the plurality of power rails is electrically coupled to a through-silicon via included in the first semiconductor substrate.

7. The packaged integrated circuit device of claim 1, wherein the first semiconductor substrate includes a plurality of through-silicon vias that are electrically coupled to the region of power delivery layers.

8. The packaged integrated circuit device of claim 1, further comprising a heat-spreader layer disposed on the first side of the second semiconductor substrate.

9. The packaged integrated circuit device of claim 8, wherein the heat-spreader layer comprises chemical-vapor deposition diamond, silver (Ag), copper (Cu), gold (Au), aluminum nitride (AlN), silicon carbide (SiC), aluminum (Al), tungsten (W), or graphite.

10. The packaged integrated circuit device of claim 8, wherein the heat-spreader layer is disposed proximate to a processing core of the integrated circuit.

11. The packaged integrated circuit device of claim 8, wherein the heat-spreader layer contacts one or more heat-transfer vias included in the second semiconductor substrate.

12. The packaged integrated circuit device of claim 1, wherein the second semiconductor substrate includes one or more heat-transfer vias.

13. The packaged integrated circuit device of claim 12, wherein the one or more heat-transfer vias are disposed proximate to a processing core of the integrated circuit.

14. The packaged integrated circuit device of claim 1, wherein the fluidic channels comprise an array of projections that reside on the second side of the second semiconductor substrate.

15. A card-based processing subsystem comprising:
a printed circuit board; and
a packaged integrated circuit device that is mounted on the printed circuit board and comprises:
a first semiconductor substrate that includes:
an integrated circuit,
a region of signal layers residing on a first side of the first semiconductor substrate, and
a region of power delivery layers residing on a second side of the first semiconductor substrate; and
a second semiconductor substrate coupled to the region of signal layers, wherein a first side of the second semiconductor substrate is coupled to the region of signal layers, and a second side of the second semiconductor substrate includes a plurality of fluidic channels.

16. The card-based processing subsystem of claim 15, further comprising a lid structure that is coupled to the second side of the second semiconductor substrate and encloses the plurality of fluidic channels.

17. The card-based processing subsystem of claim 15, wherein the region of power delivery layers includes a plurality of power rails for distributing power to the integrated circuit.

18. The card-based processing subsystem of claim 17, wherein each power rail in the plurality of power rails is electrically coupled to a through-silicon via included in the first semiconductor substrate.

19. The card-based processing subsystem of claim 15, wherein the first semiconductor substrate includes a plurality of through-silicon vias that are electrically coupled to the region of power delivery layers.

20. The card-based processing subsystem of claim 15, further comprising a heat-spreader layer disposed on the first side of the second semiconductor substrate.
